(19) United States
(12) Patent Application Publication
(10) Pub. No.: US 2026/0247093 A1
(43) Pub. Date: Aug. 20, 2026

(54) CONTEXT AWARE AUDIO CAPTURE AND RENDERING

(71) Applicant: DOLBY LABORATORIES LICENSING CORPORATION

(72) Inventors: Yuanxing MA, Beijing (CN); Zhiwei Shuang, Beijing (CN); Yang LIU, Beijing (CN); Ziyu YANG, Beijing (CN)

(73) Assignee: DOLBY LABORATORIES LICENSING CORPORATION, (US)

(21) Appl. No.: 18/851,908

(22) PCT Filed: Mar. 17, 2023
(86) PCT No.: PCT/US2023/015561

§ 371 Date: Sep. 27, 2024

Related U.S. Application Data
(60) Provisional application No. 63/336,424, filed on Apr. 29, 2022.

(30) Foreign Application Priority Data
Mar. 29, 2022 (WO) PCT/CN2022/083675

(51) Int. Cl. H04S 7/00; H03G 5/16

(52) U.S. Cl. CPC H04S 7/302; H03G 5/165

(57) ABSTRACT

Embodiments are disclosed for context aware capture and rendering. In an embodiment, an audio processing method comprises: capturing a multi-channel input audio signal; generating noise-reduced target sound events of interest and environment noise for each channel of the multi-channel input audio signal; determining an event type for rendering; selecting a rendering scheme based on the event type and a loudspeaker layout; and rendering a multichannel output audio signal using the selected rendering scheme.

### CROSS REFERENCE TO RELATED APPLICATIONS

This application claims priority to International Patent Application PCT/CN2022/083675, filed 29 Mar. 2022 and U.S. provisional application 63/336,424, filed 29 Apr. 2022, all of which are incorporated herein by reference in their entirety.

### TECHNICAL FIELD

This disclosure relates generally to audio signal processing, and more particularly to user-generated content (UGC) creation and playback.

### BACKGROUND

UGC is typically created by consumers and can include any form of content (e.g., images, videos, text, audio). UGC is typically posted by its creator to online platforms, including but not limited to social media, blogs, Wiki™ and the like. One trend related to UGC is personal moment sharing in variable environments (e.g., indoors, outdoors, by the sea) by recording video and audio using a personal mobile device (e.g., smart phone, tablet computer, wearable devices). Most UGC content contains audio artifacts due to consumer hardware limitations and a non-professional recording environment. The traditional way of UGC processing is based on audio signal analysis or artificial intelligence (AI) based noise reduction and enhancement processing. One difficulty in processing UGC is how to treat different sound types in different audio environments while maintaining the creative objective of the content creator.

### SUMMARY

Embodiments are disclosed for context aware audio capture and rendering. In an embodiment, an audio processing method comprises: capturing a multichannel input audio signal; generating noise-reduced target sound events of interest and environment noise for each channel of the multichannel input audio signal; determining an event type for rendering; selecting a rendering scheme based on the event type and a speaker layout; and rendering a multichannel output audio signal using the selected rendering scheme.

In some embodiments, the event type is determined for each channel of the multichannel input audio signal based on context information and the target sound events.

In some embodiments, the context information is generated from a context analysis of at least one of input audio, input video or sensor input.

In some embodiments, the event type is determined, using a machine learning model, as an indoor event or an outdoor event based on the context information and the target sound events.

In some embodiments, for each sound event, the sound event type indicates one of a center, surround or height rendering event, wherein for the center rendering event, the rendering is distributed across the speaker layout to create a solid center position in the sound field for the target sound event, and for the surround rendering event the rendering is distributed across the speaker layout to provide a wide sound field, and for the height rendering event the rendering is distributed across the speaker layout to emphasize enhanced height effects.

In some embodiments, the speaker layout includes three speakers including left and right speakers and a top speaker, and wherein the rendering is distributed across the left and right speakers to provide a wide sound field and distributed to the top speaker to emphasize enhanced height effects.

In some embodiments, the speaker layout includes four speakers including top left and top right speakers and bottom left and bottom right speakers, wherein for the center rendering event, the rendering is distributed across all four speakers, for the surround rendering event, the rendering is distributed across the bottom left and right speakers to provide a wide sound field, and for the height rendering event the rendering is distributed across the top left and top right speakers to emphasize enhanced height effects.

In some embodiments, the event types are determined during capture of the multichannel input audio signal, and the event types are stored as metadata for the selection of rendering scheme in subsequent rendering.

In some embodiments, a format of the metadata depends on whether the capture of the multichannel input audio signal and the rendering are performed by the same device.

In some embodiments, the method further comprises: applying at least one of equalization or dynamic range control to the rendered multichannel output audio signal.

In some embodiments, rendering the multichannel output audio signal includes applying a mix ratio to the target sound events and the environment noise based on the event type.

In some embodiments, the multichannel output audio signal is rendered by a mobile device that includes a folding screen, and the method further comprises: determining, with the at least one processor, whether the screen is folded or unfolded; and in accordance with the determining, selecting a first speaker layout for rendering if the screen is folded and a second speaker layout if the screen is unfolded, where the first speaker layout is different than the second speaker layout.

In some embodiments, a system of processing audio, comprising: one or more processors; and a non-transitory computer-readable medium storing instructions that, when executed by the one or more processors, cause the one or more processors to perform any of the preceding methods.

In some embodiments, a non-transitory computer-readable medium storing instructions that, when executed by the one or more processors, cause the one or more processors to perform any of the preceding methods.

Particular embodiments disclosed herein provide one or more of the following advantages. The disclosed context aware audio capturing and rendering embodiments can be used for binaural recordings to capture a realistic binaural soundscape while maintaining the creative objective of the content creator.

### DESCRIPTION OF DRAWINGS

In the drawings, specific arrangements or orderings of schematic elements, such as those representing devices, units, instruction blocks and data elements, are shown for ease of description. However, it should be understood by those skilled in the art that the specific ordering or arrangement of the schematic elements in the drawings is not meant to imply that a particular order or sequence of processing, or separation of processes, is required. Further, the inclusion of a schematic element in a drawing is not meant to imply that such element is required in all embodiments or that the features represented by such element may not be included in or combined with other elements in some embodiments.

Further, in the drawings, where connecting elements, such as solid or dashed lines or arrows, are used to illustrate a connection, relationship, or association between or among two or more other schematic elements, the absence of any such connecting elements is not meant to imply that no connection, relationship, or association can exist. In other words, some connections, relationships, or associations between elements are not shown in the drawings so as not to obscure the disclosure. In addition, for ease of illustration, a single connecting element is used to represent multiple connections, relationships or associations between elements. For example, where a connecting element represents a communication of signals, data, or instructions, it should be understood by those skilled in the art that such element represents one or multiple signal paths, as may be needed, to affect the communication.

FIG. 1 illustrates binaural recording using earbuds and a mobile device, according to an embodiment.

FIG. 2A illustrates the capture of audio when the user is holding the mobile device in a front-facing position, according to an embodiment.

FIG. 2B illustrates the capture of audio when the user is holding the mobile device in a rear-facing or “selfie” position, according to an embodiment.

FIG. 3A illustrates a three speaker layout for a smartphone with a foldable screen, according to an embodiment.

FIG. 3B illustrates a four speaker layout for the smartphone of FIG. 3A when the screen is unfolded, according to an embodiment.

FIG. 4 illustrates a speaker layout where the speakers are firing upwards and downwards, according to an embodiment.

FIG. 5 illustrates a speaker layout where the speakers are firing sideways, according to an embodiment.

FIG. 6 is a block diagram of a noise reduction unit that generates noise-reduced target sound events of interest and environment noise, according to an embodiment.

FIG. 7 is a block diagram of context aware event type classification, according to an embodiment.

FIG. 8 illustrates rendering across multiple speakers based on event type and speaker layout, according to an embodiment.

FIG. 9 is a flow diagram of a process of context aware audio capture and rendering, according to an embodiment.

FIG. 10 is a block diagram of an example device architecture for implementing the features and processes described in reference to FIGS. 1-9, according to an embodiment.

The same reference symbol used in various drawings indicates like elements.

### DETAILED DESCRIPTION

In the following detailed description, numerous specific details are set forth to provide a thorough understanding of the various described embodiments. It will be apparent to one of ordinary skill in the art that the various described embodiments may be practiced without these specific details. In other instances, well-known methods, procedures, components, and circuits, have not been described in detail so as not to unnecessarily obscure aspects of the embodiments. Several features are described hereafter that can each be used independently of one another or with any combination of other features.

The disclosed context aware audio capture and rendering is comprised of the following steps. First, a binaural capture device (e.g., a pair of earbuds) records a multichannel input audio signal (e.g., binaural left (L) and right (R)), and a playback device (e.g., smartphone, tablet computer or other device) that renders the multichannel audio recording through multiple speakers. The recording device and the playback device can be the same device, two connected devices, or two separate devices. The speaker count used for multi-speaker rendering is at least three. In some embodiments, the speaker count is three. In other embodiments, the speaker count is four.

The capture device comprises a context detection unit to detect the context of the audio capture, and the audio processing and rendering is guided based on the detected context. In some embodiments, the context detection unit includes a machine learning model (e.g., an audio classifier) that classifies a captured environment into several event types. For each event type, a different audio processing profile is applied to create an appropriate rendering through multiple speakers. In some embodiments, the context detection unit is a scene classifier based on visual information which classifies the environment into several event types. For each event type, a different audio processing profile is applied to create appropriate rendering through multiple speakers. The context detection unit can also be based on combination of visual information, audio information and sensor information.

In some embodiments, the capture device or the playback device comprises at least a noise reduction system, which generates noise-reduced target sound events of interest and residual environment noise. The target sound events of interest are further classified into different event types by an audio classifier. Some examples of target sound events include but are not limited to speech, noise or other sound events. The source types are different in different capture contexts according to the context detection unit.

In some embodiments, the playback device renders the target sound events of interest across multiple speakers by applying a different mix ratio of sound source and environment noise, and by applying different equalization (EQ) and dynamic range control (DRC) according to the classified event type.

### Nomenclature

As used herein, the term “includes” and its variants are to be read as open-ended terms that mean “includes, but is not limited to.” The term “or” is to be read as “and/or” unless the context clearly indicates otherwise. The term “based on” is to be read as “based at least in part on.” The term “one example embodiment” and “an example embodiment” are to be read as “at least one example embodiment.” The term “another embodiment” is to be read as “at least one other embodiment.” The terms “determined,” “determines,” or “determining” are to be read as obtaining, receiving, computing, calculating, estimating, predicting or deriving. In addition, in the following description and claims, unless defined otherwise, all technical and scientific terms used herein have the same meaning as commonly understood by one of ordinary skills in the art to which this disclosure belongs.

### Example System

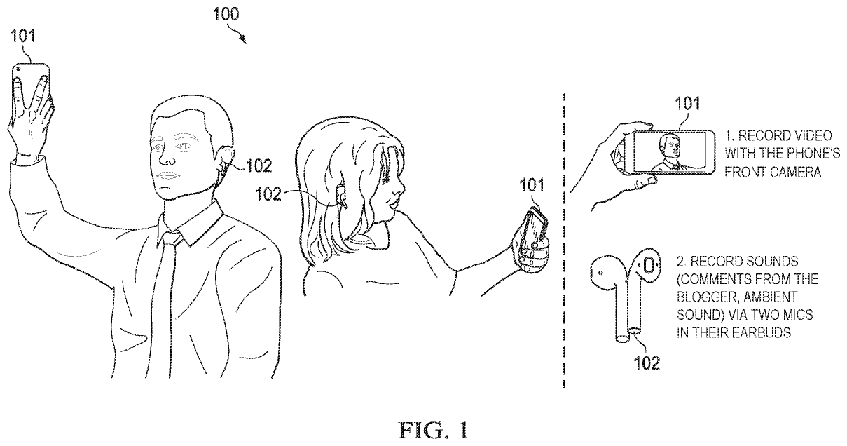

FIG. 1 illustrates binaural recording using earbuds 102 and a mobile device 101, according to an embodiment. System 100 includes a two-step process of recording video with a video camera of mobile device 101 (e.g., a smartphone), and concurrently recording audio associated with the video recording. In an embodiment, the audio recording can be made by, for example, mobile device 101 recording audio signals output by microphones embedded in earbuds 102. The audio signals can include but are not limited to comments spoken by a user and/or ambient sound. If both the left and right microphones are used then a binaural recording can be captured. In some implementations, microphones embedded or attached to mobile device 101 can also be used.

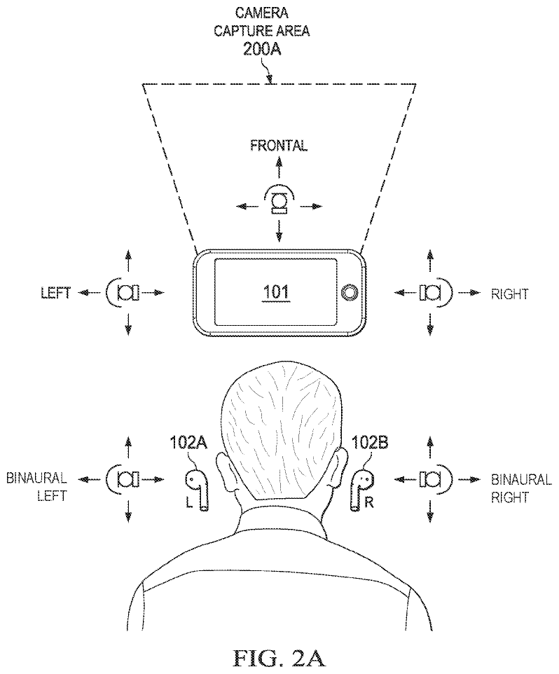

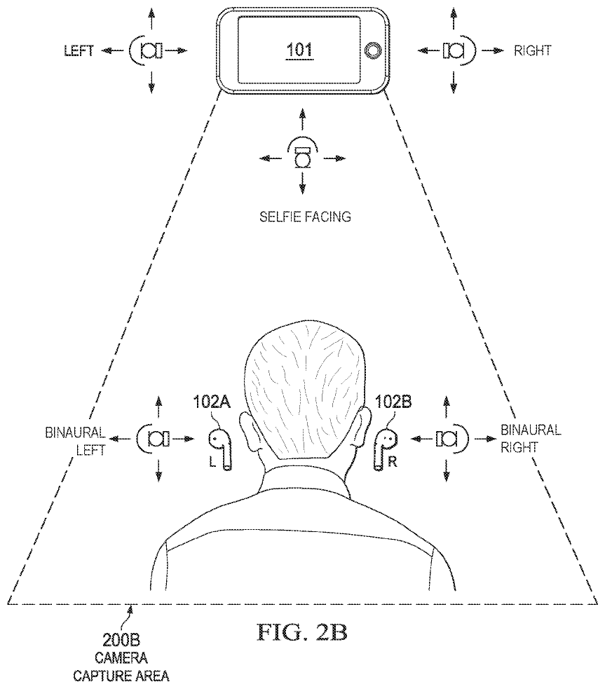

FIG. 2A illustrates the capture of audio when the user is holding mobile device 101 in a front-facing position and using a rear-facing camera, according to an embodiment. In this example, camera capture area 200a is in front of the user. The user is wearing earbuds 102a, 102b that each include a microphone which captures left/right (binaural) sounds, respectively, and combined into a binaural recording stream. Microphones 103a-103c embedded in mobile device 101 capture left, frontal and right sounds, respectively, and generate an audio recording stream that is synchronized with the binaural recording stream and rendered on loudspeakers embedded in or coupled to mobile device 101.

FIG. 2B illustrates the capture of audio when the user is holding the mobile device in a front-facing position (“selfie” mode) and using the front-facing camera, according to an embodiment. In this example, camera capture area 200b is behind the user. The user is wearing earbuds 102a, 102b that each include a microphone which captures left/right (binaural) sound, respectively. Microphones 103a-103c embedded in mobile device 101 capture left, frontal and right sound, respectively, and generate an audio recording stream that is synchronized with the binaural recording stream and rendered on loudspeakers coupled to mobile device 10.

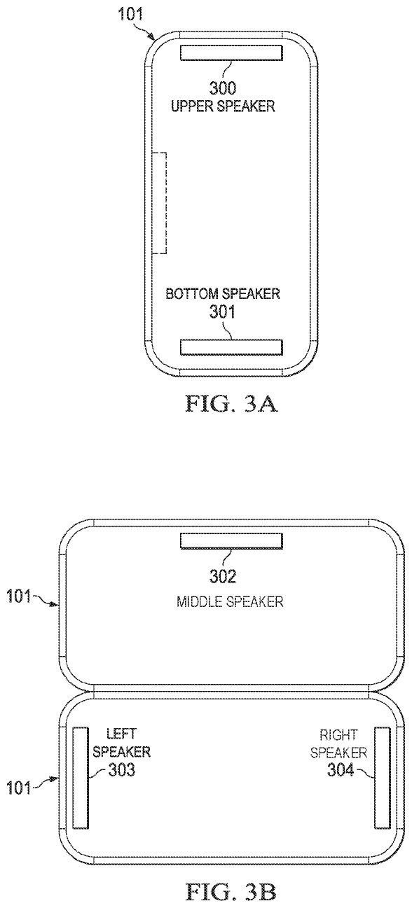

FIG. 3A illustrates a three speaker layout for mobile device 101 with a folding screen when the screen is in a folded mode, according to an embodiment. Mobile device 101 is shown in folded mode with upper speaker 300 and bottom speaker 301.

FIG. 3B illustrates a three speaker layout for the smartphone of FIG. 3A when the screen is unfolded, according to an embodiment. Mobile device 101 is shown in unfolded mode with left speaker 303 on the lower left, right speaker 304 on lower right and middle speaker 302 on top.

As illustrated by the example mobile device 101 shown in FIGS. 3A and 3B, there are many different kinds of speaker layouts and placement on mobile device 101 (e.g., a smartphone, tablet computer). For example, a smart phone can have two symmetric speakers to represent the left and right sound field in landscape mode or it can also have three speakers with two speakers to represent the left and right sound field and one up-firing or face-firing speaker to represent the middle and upper parts of the sound field.

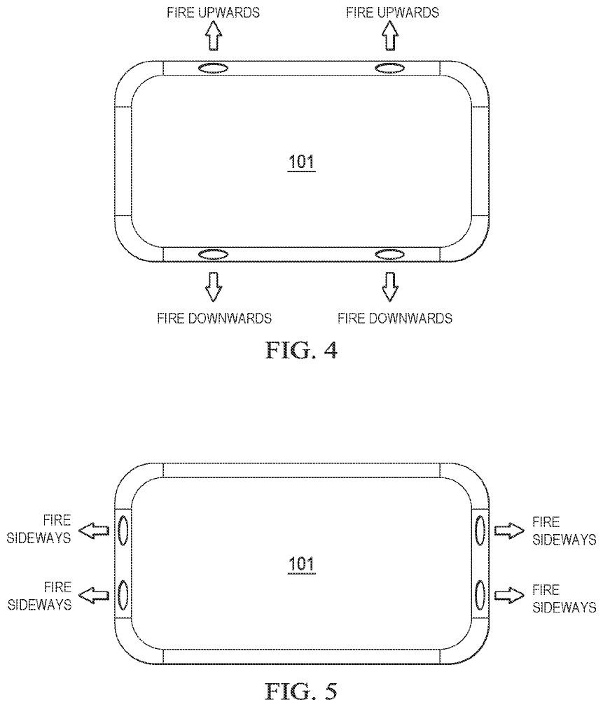

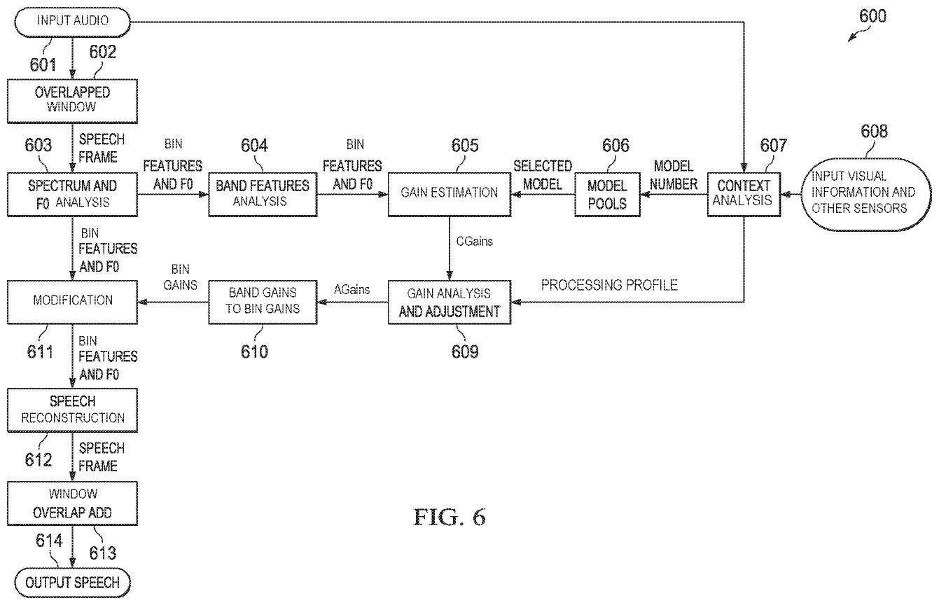

FIG. 4 illustrates a speaker layout where the speakers are firing upwards and downwards, and FIG. 5 illustrates a speaker layout where the speakers are firing sideways.

For another example, a tablet computer can have four speakers to represent the left and right sound field (e.g., two speakers on the left channel, two speakers on the right channel). The tablet computer can also have four individual speakers which have a symmetric layout to represent the left, right, the left-height and the right-height parts of the sound field. Audio rendering is used to adaptively distribute the audio signals to these different speaker layouts and placements with an appropriate gain.

FIG. 6 is a block diagram of a system 600 for context aware audio processing, according to an embodiment. System 600 includes window processor 602, spectrum analyzer 603, band feature analyzer 604, gain estimator 605, machine learning model 606, context analyzer 607, gain analyzer/adjuster 609, band gain-to-bin gain converter 610, spectrum modifier 611, speech reconstructor 612 and window overlap-add processor 613.

Window processor 602 generates a speech frame comprising overlapping windows of samples of input audio 601 containing speech (e.g., an audio recording captured by mobile device 101). The speech frame is input into spectrum analyzer 603 which generates frequency bin features and a fundamental frequency (F0). The analyzed spectrum information can be represented by: a Fast Fourier transform (FFT) spectrum, Quadrature Mirror Filter (QMF) features or any other audio analysis process. The bins are scaled by spectrum modifier 611 and input into speech reconstructor 612 which outputs a reconstructed speech frame. The reconstructed speech frame is input into window overlap-add processor 613, which generates output speech.

Referring back to step 603 the bin features and F0 are input into band feature analyzer 604, which outputs band features and F0. In an embodiment, the band features are extracted based on FFT parameters. Band features can include but are not limited to: Mel-frequency cepstral coefficients (MFCC) and Bark-frequency cepstral coefficients (BFCC). In an embodiment, a band harmonicity feature can be computed, which indicates how much a current frequency band is composed of a periodic signal. In an embodiment, the harmonicity feature can be calculated based on FFT frequency bins of a current speech frame by correlating the current speech frame and a previous speech frame.

The band features and F0 are input into gain estimator 605 which estimates gains (CGains) for noise reduction based on a model selected from model pool 606. In an embodiment, the model is selected based on a model number or other data output by context analyzer 607 in response to input visual information and/or other sensor information. In an embodiment, the model is a deep neural network (DNN) trained to estimate gains and voice activity detection (VAD) for each frequency band based on the band features and F0. The DNN model can be based on a fully connected neural network (FCNN), recurrent neural network (RNN) or convolutional neural network (CNN) or any combination of FCNN, RNN and CNN. In an embodiment, a Wiener Filter or other suitable estimator can be combined with the DNN model to get the final estimated gains for noise reduction.

The estimated gains, CGains, are input into gain analyzer/adjuster 609 which generates adjusted gains, AGains, based on an audio processing profile. AGains is input into band gain-to-bin-gain converter 610, which generates adjusted bin gains. The adjusted bin gains are input into spectrum modifier 611, which applies the adjusted bin gains to their corresponding frequency bins (e.g., scales the bin magnitudes by their respective adjusted bin gains). The adjusted bin features are then input into speech reconstructor 612, which outputs a reconstructed speech frame. The reconstructed speech frame is input into window overlap-add processor 612, which generates reconstructed output speech using an overlap and add algorithm.

In some embodiments, the model number or other data for identifying a model in a pool of models is output by context analyzer 607 based on input audio 601 and/or input visual information and/or other sensors data 608. Context analyzer 607 can include one or more audio scene classifiers trained to classify audio content into one or more classes representing recording locations. In some embodiments, the recording location classes are indoors, outdoors and transportation. For each class, a specific audio processing profile can be assigned. In some embodiments, context analyzer 607 is trained to classify a more specific recording location (e.g., sea bay, forest, concert, meeting room, etc.).

In some embodiments, context analyzer 607 is trained using visual information, such as digital pictures and video recordings, or a combination of an audio recording and visual information. In other embodiments, other sensor data can also be used to determine context alone or in combination with audio and visual information, such as inertial sensors (e.g., accelerometers, gyros) or position technologies, such as global navigation satellite systems (GNSS), cellular networks or Wi-Fi fingerprinting. For example, an accelerometer and gyroscope and/or Global Position System (GPS) data can be used to determine a speed of mobile device 101. The speed can be combined with the audio recording and/or visual information to determine whether the mobile device 101 is being transported (e.g., in a vehicle, bus, airplane, etc.).

In an embodiment, different models can be trained for different scenarios to achieve better performance. The training data can be adjusted to achieve different model behaviors. When a model is trained, the training data can be separated into two parts: (1) a target audio database containing signal portions of the input audio to be maintained in the output speech, and (2) a noise audio database which contains noise portions of the input audio that needs to be suppressed in the output speech. Different training data can be defined to train different models for different recording locations. For example, for the sea bay model, the sound of tides can be added to the target audio database to make sure the model maintains the sound of tides.

After defining the specific training database, traditional training procedures can be used to train the models (e.g., back propagation) In an embodiment, the context information can be mapped to a specific audio processing profile. The specific audio processing profile can include a least a specific mixing ratio for mixing the input audio (e.g., the original audio recording) with the processed audio recording where environment noise was suppressed. The mix ratio is controlled by context analyzer 607. The mixing ratio can be applied in the time domain, or the CGains can be adjusted with the mixing ratio according to Equation [1] by gain adjuster 609, as described below.

Although a DNN based noise reduction algorithm can suppress noise significantly, the noise reduction algorithm may also introduce artifacts in the output speech, or remove some target sound events of interest. Thus, to reduce the artifacts, and recover the target sound events of interest, the processed audio recording is mixed with the original audio recording. In an embodiment, a fixed mixing ratio can be used. For example, the mixing ratio can be 0.25.

However, a fixed mixing ratio may not work for different contexts. Therefore, in an embodiment the mixing ratio can be adjusted based on the recording context output by context analyzer 607. To achieve this, the context is estimated based on the input audio information. For example, for the indoor class, a larger mixing ratio (e.g., 0.35) can be used. For the outdoor case, a lower mixing ratio (e.g., 0.25) can be used. For the transportation class, an even lower mixing ratio can be used (e.g., 0.2). In an embodiment where a more specific recording location can be determined, a different audio processing profile can be used. For example, for meeting room, a small mixing ratio (e.g., 0.1), can be used to remove more noise. For a concert, a larger mixing ratio such as 0.5 can be used to avoid degrading the music quality.

In an embodiment, mixing the original audio recording with the processed audio recording can be implemented by mixing the denoised audio file with the original audio file in the time domain. In another embodiment, the mixing can be implemented by adjusting the CGains with the mixing ratio dMixRatio, according to Equation [1]:

$$AGains = CGains + dMixRatio , where if CGains > 1 , r = 1. \qquad [ 1 ]$$

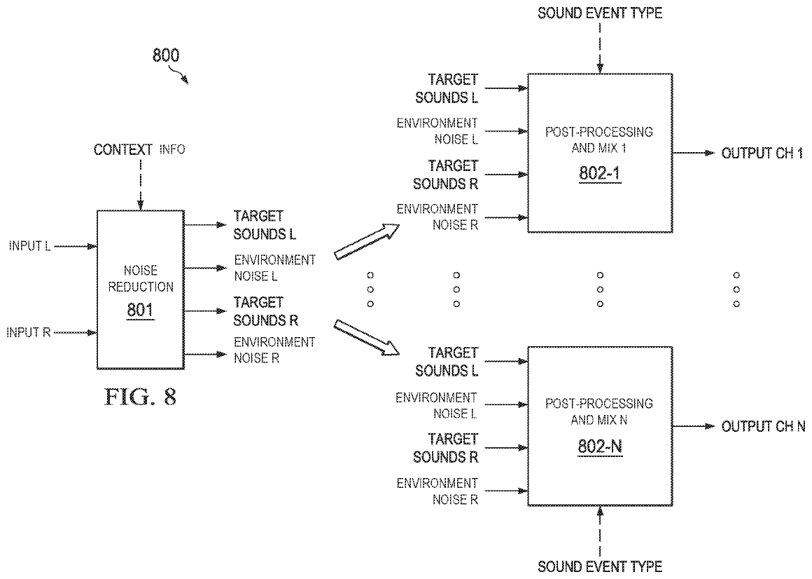

In some embodiments, the specific audio processing profile also includes an EQ curve and/or a DRC data, which can be applied in a post processing step, as described below in reference to FIG. 8. The sound event type and context information can be stored as metadata and shared between the capture device and the playback device. For example, if the recording location is identified as a concert, a music specific EQ curve can be applied to the output of system 600 to preserve the timbre of various music instruments, and/or the DRC can be configured to do less compressing to make sure the music level is within a certain loudness range suitable for music. In a speech dominant audio scene, the EQ curve could be configured to enhance speech quality and intelligibility (e.g., boost at 1 KHz), and the DRC can be configured to do more compressing to make sure the speech level is within a certain loudness range suitable for speech.

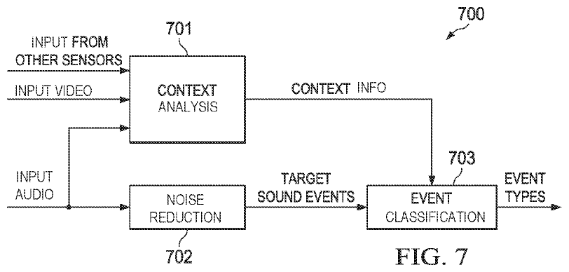

FIG. 7 is a block diagram of context aware event classification module 700, according to an embodiment. Event classification unit 700 includes context analysis unit 701, noise reduction unit 702 and event classifier 703. Noise reduction unit 702 can be implemented using noise reduction system 600, as described in reference to FIG. 6. Noise reduction unit 702 generates noise reduced target sound events of interest. The target sound events of interest are further classified to different event types by audio event classifier 703, to choose a proper rendering scheme based on the context information (e.g., sound source type) determined and output by context analysis unit 710. More particularly, context analysis unit 701 takes input audio, video, and sensor data and generates the context information of the current capture. The input audio is feed into noise reduction unit 702 first, which generates noise-reduced target sound events.

Event classifier unit 703 takes the noise-reduced target sound events and determines event types for rendering based on the context information output by context analysis unit 701. In some embodiments, the context information can be an indoor/outdoor classification, where a different classifier model is used, as the sound events differ. The event type can be used for selecting a rendering scheme from a plurality of rendering streams on multiple speakers. In some embodiments, the event types can be “center,” “surround” and “height.”

In some embodiments, the event types can be determined during capture of the audio. In some embodiments, the event types are transmitted in a metadata stream together or separately from the audio data. The metadata stream format can be different when the capture device and playback device are the same device, and when they are different devices.

FIG. 8 illustrates context aware rendering across multiple speakers based on event type, according to an embodiment. To render content across multiple speakers, the multichannel input audio signal is first processed by context aware noise reduction unit 801 (e.g., using context aware noise reduction system 600 shown in FIG. 6) to generate target sound events of interest and environment noise (e.g., residual environment noise) for channel L and channel R.

In some embodiments, context aware noise reduction unit 801 takes as input the context information output by context analysis unit 701 shown in FIG. 7, which can be stored as metadata to be shared between the capture device and playback device. To avoid duplicated computation, in some embodiments the band gains (output from gain estimator 605) that are calculated in noise reduction unit 702 can also be stored as metadata and applied by context aware noise reduction unit 801 directly by gain adjustor 609.

To generate output for each speaker, target sound events L, environment noise L, target sound events R and environment noise R are processed by a corresponding post-processing and mix module 802a . . . 802n. Post processing mix modules 802a . . . 802n applies at least EQ and DRC to the inputs, and a mix is achieved by applying a mix ratio to each input. The post processing and mix ratio for each output channel is based on the event type, thus different rendering schemes are applied for different sound events.

In the example, the speaker layout and placement includes three speakers as shown in FIG. 3B (unfolded screen), where the left and right speakers are at lower left and lower right, and the middle speaker is on the top. In some embodiments, the sound event types can be “center rendering event,” “surround rendering event” and “height rendering event.” For center rendering events, the rendering is distributed across left, right and middle speakers to create a solid sound source in the center channel of the sound fields. For surround rendering events, the rendering is emphasized on the left and right speakers to provide a wide sound field. For height rendering events, the rendering is emphasized on the middle speaker to enhance height effects.

In another example, the speaker layout and placement for four speakers as shown in FIGS. 4 and 5. In some embodiments, the sound event types can be “center rendering event” “surround rendering event” and “height rendering event.” For center rendering events, the rendering is distributed across all four speakers to create a solid sound source in the center channel. For surround rendering events, the rendering is emphasized on the lower left and lower right speakers to provide a wide sound field. For height rendering events, the rendering is emphasized on the top left and top right speakers to enhance height effects.

### Example Process

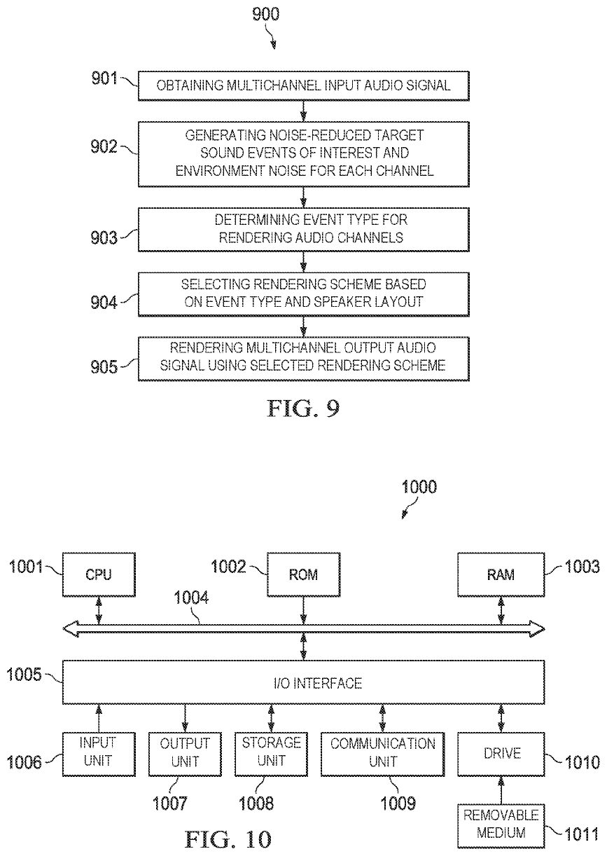

FIG. 9 is a flow diagram of process 900 of context aware capture and rendering, according to an embodiment. Process 900 can be implemented using, for example, device architecture 1000 described in reference to FIG. 10.

Process 900 includes the steps of: capturing a multichannel input audio signal (901), generating noise-reduced target sound events of interest and environment noise for each channel of the multichannel input audio signal (902); determining an event type for rendering (903); selecting a rendering scheme based on the event type and a speaker layout (904); and rendering a multichannel output audio signal using the selected rendering scheme (905). Each of these steps were previously described in detail above in reference to FIGS. 1-8.

### Example System Architecture

FIG. 1000 shows a block diagram of an example system 1000 suitable for implementing example embodiments described in reference to FIGS. 1-9. System 1000 includes a central processing unit (CPU) 1001 which is capable of performing various processes in accordance with a program stored in, for example, a read only memory (ROM) 1002 or a program loaded from, for example, a storage unit 1008 to a random access memory (RAM) 1003. In the RAM 1003, the data required when the CPU 1001 performs the various processes is also stored, as required. The CPU 1001, the ROM 1002 and the RAM 1003 are connected to one another via a bus 1004. An input/output (I/O) interface 1005 is also connected to the bus 1004.

The following components are connected to the I/O interface 1005: an input unit 1006, that may include a keyboard, a mouse, or the like; an output unit 1007 that may include a display such as a liquid crystal display (LCD) and one or more speakers; the storage unit 1008 including a hard disk, or another suitable storage device; and a communication unit 1009 including a network interface card such as a network card (e.g., wired or wireless).

In some embodiments, the input unit 1006 includes one or more microphones in different positions (depending on the host device) enabling capture of audio signals in various formats (e.g., mono, stereo, spatial, immersive, and other suitable formats).

In some embodiments, the output unit 1007 include systems with various number of speakers. The output unit 1007 can render audio signals in various formats (e.g., mono, stereo, immersive, binaural, and other suitable formats).

The communication unit 1009 is configured to communicate with other devices (e.g., via a network). A drive 1010 is also connected to the I/O interface 1005, as required. A removable medium 1011, such as a magnetic disk, an optical disk, a magneto-optical disk, a flash drive or another suitable removable medium is mounted on the drive 1010, so that a computer program read therefrom is installed into the storage unit 1008, as required. A person skilled in the art would understand that although the system 1000 is described as including the above-described components, in real applications, it is possible to add, remove, and/or replace some of these components and all these modifications or alteration all fall within the scope of the present disclosure.

In accordance with example embodiments of the present disclosure, the processes described above may be implemented as computer software programs or on a computer-readable storage medium. For example, embodiments of the present disclosure include a computer program product including a computer program tangibly embodied on a machine readable medium, the computer program including program code for performing methods. In such embodiments, the computer program may be downloaded and mounted from the network via the communication unit 709, and/or installed from the removable medium 1011, as shown in FIG. 10.

Generally, various example embodiments of the present disclosure may be implemented in hardware or special purpose circuits (e.g., control circuitry), software, logic or any combination thereof. For example, the units discussed above can be executed by control circuitry (e.g., a CPU in combination with other components of FIG. 10), thus, the control circuitry may be performing the actions described in this disclosure. Some aspects may be implemented in hardware, while other aspects may be implemented in firmware or software which may be executed by a controller, microprocessor or other computing device (e.g., control circuitry). While various aspects of the example embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

Additionally, various blocks shown in the flowcharts may be viewed as method steps, and/or as operations that result from operation of computer program code, and/or as a plurality of coupled logic circuit elements constructed to carry out the associated function(s). For example, embodiments of the present disclosure include a computer program product including a computer program tangibly embodied on a machine readable medium, the computer program containing program codes configured to carry out the methods as described above.

In the context of the disclosure, a machine readable medium may be any tangible medium that may contain, or store a program for use by or in connection with an instruction execution system, apparatus, or device. The machine readable medium may be a machine readable signal medium or a machine readable storage medium. A machine readable medium may be non-transitory and may include but not limited to an electronic, magnetic, optical, electromagnetic, infrared, or semiconductor system, apparatus, or device, or any suitable combination of the foregoing. More specific examples of the machine readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Computer program code for carrying out methods of the present disclosure may be written in any combination of one or more programming languages. These computer program codes may be provided to a processor of a general purpose computer, special purpose computer, or other programmable data processing apparatus that has control circuitry, such that the program codes, when executed by the processor of the computer or other programmable data processing apparatus, cause the functions/operations specified in the flowcharts and/or block diagrams to be implemented. The program code may execute entirely on a computer, partly on the computer, as a stand-alone software package, partly on the computer and partly on a remote computer or entirely on the remote computer or server or distributed over one or more remote computers and/or servers.

While this document contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can, in some cases, be excised from the combination, and the claimed combination may be directed to a sub combination or variation of a sub combination. Logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

What is claimed is:

1. An audio processing method, comprising:
capturing, with at least one processor, a multichannel input audio signal;
generating, with the at least one processor, noise-reduced target sound events of interest and environment noise for each channel of the multichannel input audio signal;
determining, with the at least one processor, an event type for rendering;
selecting, with the at least one processor, a rendering scheme based on the event type and a speaker layout; and
rendering, with the at least one processor, a multichannel output audio signal using the selected rendering scheme.

2. The method of claim 1, wherein the event type is determined for each target sound event of the multichannel input audio signal by event classification.

3. The method of claim 2, wherein the event classification is steered by context information.

4. The method of claim 3, wherein the context information is generated from a context analysis of at least one of input audio, input video or sensor input.

5. The method of claim 3, wherein the context information is determined, using a machine learning model, as an indoor context or an outdoor context.

6. The method of claim 1, wherein, for each target sound event, the sound event type indicates one of a center rendering event, surround rendering event or height rendering event, wherein for the center rendering event, the rendering is distributed across the speaker layout to create a center channel position in the sound field for the target sound event, and for the surround rendering event, the rendering is distributed across the speaker layout to provide a wide sound field, and for the height rendering event, the rendering is distributed across the speaker layout to emphasize enhanced height effects.

7. The method of claim 1, wherein the speaker layout includes three speakers including left and right speakers and a top speaker, and wherein the rendering is distributed across the left and right speakers to provide a wide sound field and distributed to the top speaker to emphasize enhanced height effects.

8. The method of claim 1, wherein the speaker layout includes four speakers including top left and top right speakers and bottom left and bottom right speakers, wherein for the center rendering event, the rendering is distributed across all four speakers, for the surround rendering event, the rendering is distributed across the bottom left and right speakers to provide a wide sound field, and for the height rendering event, the rendering is distributed across the top left and top right speakers to emphasize enhanced height effects.

9. The method of claim 1, wherein the sound event type is determined during capture of the multichannel input audio signal, and stored as metadata for rendering scheme selection in subsequent rendering.

10. The method of claim 9, wherein a format of the metadata depends on whether the capture of the multichannel input audio signal and the rendering are performed by the same device.

11. The method of any of claim 1, further comprising:
applying at least one of equalization or dynamic range control to the rendered multichannel output audio signal.

12. The method of claim 1, wherein rendering the multichannel output audio signal includes applying a mix ratio to the target sound events and the environment noise based on the event type.

13. The method of claim 1, wherein the multichannel input audio signal is rendered by a mobile device that includes a folding screen, and the method further comprises:
determining, with the at least one processor, whether the screen is folded or unfolded; and
in accordance with the determining, selecting a first speaker layout for rendering if the screen is folded and a second speaker layout if the screen is unfolded, where the first speaker layout is different than the second speaker layout.

14. A system of processing audio, comprising:
one or more processors; and
a non-transitory computer-readable medium storing instructions that, when executed by the one or more processors, cause the one or more processors to perform operations of claim 1.

15. A non-transitory computer-readable medium storing instructions that, when executed by the one or more processors, cause the one or more processors to perform operations of claim 1.
